(19) United States
(12) Patent Application Publication
(10) Pub. No.: US 2025/0033143 A1
(43) Pub. Date: Jan. 30, 2025

(54) APPARATUS FOR SUBSTRATE DICING

(71) Applicant: SAMSUNG ELECTRONICS CO., LTD., Suwon-si (KR)

(72) Inventors: Dong Ju PARK, Suwon-si (KR); Young Chul KWON, Suwon-si (KR); Jae Heung LEE, Suwon-si (KR); Nam-Tae HEO, Suwon-si (KR)

(21) Appl. No.: 18/662,272

(22) Filed: May 13, 2024

(30) Foreign Application Priority Data
Jul. 25, 2023 (KR) 10-2023-0096697

(51) Int. Cl. B23K 26/042; B23K 26/03; B23K 26/064; B23K 26/53

(52) U.S. Cl. CPC B23K 26/042; B23K 26/032; B23K 26/064; B23K 26/53

(57) ABSTRACT

An apparatus for substrate dicing includes: a laser beam emitter outputting a laser beam; a stage on which a test substrate is loaded, wherein the test substrate includes a sample substrate and a test film; a laser beam modulator modulating the laser beam to output a modulated beam; an optical system transferring the modulated beam into the sample substrate; a camera capturing the modulated beam that is reflected from the test film; and a controller generating a control signal based on at least one of a reaction point being formed in the test film or a shape of the reaction point of the test film being biased toward one side with respect to a central axis, wherein the laser beam modulator is configured to modulate the laser beam based on the control signal to output the modulated beam.

### CROSS-REFERENCE TO RELATED APPLICATION

This application claims priority under 35 USC § 119 to Korean Patent Application No. 10-2023-0096697 filed on Jul. 25, 2023, in the Korean Intellectual Property Office, the disclosure of which is incorporated by reference herein in its entirety.

### TECHNICAL FIELD

Embodiments of the present inventive concept relate to an apparatus for substrate dicing.

### DISCUSSION OF THE RELATED ART

Generally, a semiconductor may be fabricated through various processes. For example, a process of cutting a wafer or the like may be included in a semiconductor fabricating process. The wafer may be cut in various ways. The wafer may be cut, for example, by using a blade or a laser. For example, to cut the wafer by using a laser, a stealth dicing method that focuses a laser beam into the wafer may be used. The wafer may be cut by focusing the laser beam into the wafer to form a crack and a reforming region inside the wafer.

### SUMMARY

According to embodiments of the present inventive concept, an apparatus for substrate dicing includes: a laser beam emitter configured to output a laser beam; a stage on which a test substrate is loaded, wherein the test substrate includes a sample substrate and a test film that is disposed on the sample substrate; a laser beam modulator configured to modulate the laser beam and to output a modulated beam; an optical system configured to transfer the modulated beam into the sample substrate; a camera configured to capture the modulated beam that is reflected from the test film; and a controller configured to generate a control signal based on at least one of a reaction point being formed in the test film or a shape of the reaction point of the test film being biased toward one side with respect to a central axis, wherein the laser beam modulator is configured to modulate the laser beam based on the control signal and to output the modulated beam that is based on the control signal, the test film includes a material for absorbing the modulated beam, and the laser beam has a power in which a reforming region is not formed in the test substrate.

According to embodiments of the present inventive concept, an apparatus for substrate dicing includes: a laser beam emitter configured to output a laser beam; a stage on which a test substrate is loaded, wherein the test substrate includes a sample substrate and a test film that is disposed on the sample substrate; a laser beam modulator configured to modulate the laser beam and to output a modulated beam; an optical system configured to transfer the modulated beam into the sample substrate; a camera configured to capture the modulated beam that is reflected from the test film to generate an image data; and a controller configured to generate a control signal based on the image data, wherein the laser beam modulator is configured to modulate the laser beam based on the control signal and to output the modulated beam that is based on the control signal, the test film includes a material for absorbing the laser beam, and the laser beam has a power in which a reforming region is not formed in the test substrate.

According to embodiments of the present inventive concept, an apparatus for substrate dicing includes: a laser beam emitter configured to output a first laser beam; a stage on which a test substrate is loaded, wherein the test substrate includes a sample substrate and a test film that is disposed on the sample substrate; a laser beam modulator configured to modulate the first laser beam; an optical system configured to transfer the modulated first laser beam into the test substrate; a camera configured to capture the modulated first laser beam that is reflected from the test film to generate image data; and a controller configured to generate a control signal based on a gray component of the image data, wherein the laser beam modulator is configured to be corrected based on the control signal, when the test substrate is unloaded from the stage and a target substrate is loaded on the stage, the laser beam emitter is configured to output a second laser beam, the corrected laser beam modulator is configured to modulate the second laser beam, and the optical system is configured to transfer the modulated second laser beam into the target substrate, and the first laser beam has a power in which a reforming region is not formed in the sample substrate.

### BRIEF DESCRIPTION OF THE DRAWINGS

The above and features of the present inventive concept will become more apparent by describing in detail embodiments thereof with reference to the attached drawings, in which:

FIG. 1 is a view illustrating an apparatus for substrate dicing according to embodiments of the present inventive concept;

FIG. 2 is a flow chart illustrating an operation of an apparatus for substrate dicing according to embodiments of the present inventive concept;

FIG. 3 is a view illustrating that spherical aberration of an apparatus for substrate dicing is normal;

FIG. 4 is a view illustrating that spherical aberration of an apparatus for substrate dicing is defective;

FIG. 5 is an example of image data obtained by capturing a test film on which a reaction point is formed;

FIG. 6 is a view illustrating that aberration of an apparatus for substrate dicing is corrected by using a laser beam modulator;

FIG. 7 is a view illustrating that aberration of an apparatus for substrate dicing is corrected by using a laser beam modulator;

FIG. 8 is a flow chart illustrating an operation of an apparatus for substrate dicing according to embodiments of the present inventive concept;

FIG. 9 is an example of image data when coma aberration of an apparatus for substrate dicing is normal;

FIG. 10 is an example of image data when coma aberration of an apparatus for substrate dicing is defective;

FIG. 11 is a view illustrating a step S230 of FIG. 8;

FIG. 12 is a view illustrating an operation method of an apparatus for substrate dicing according to embodiments of the present inventive concept;

FIG. 13 is a flow chart illustrating an operation method of an apparatus for substrate dicing according to embodiments of the present inventive concept;

FIG. 14 is a view illustrating that spherical aberration of an apparatus for substrate dicing is defective;

FIG. 15 is a view illustrating that coma aberration of an apparatus for substrate dicing is normal;

FIG. 16 is a view illustrating that coma aberration of an apparatus for substrate dicing is defective;

FIG. 17 is a view illustrating a test substrate of FIG. 1; and

FIG. 18 is a view illustrating a test substrate of FIG. 1.

### DETAILED DESCRIPTION OF THE DISCLOSURE

In the figures and the specification, like reference numerals may denote like elements or features, and thus their descriptions may be omitted.

Hereinafter, embodiments of the present inventive concept will be described with reference to the accompanying drawings.

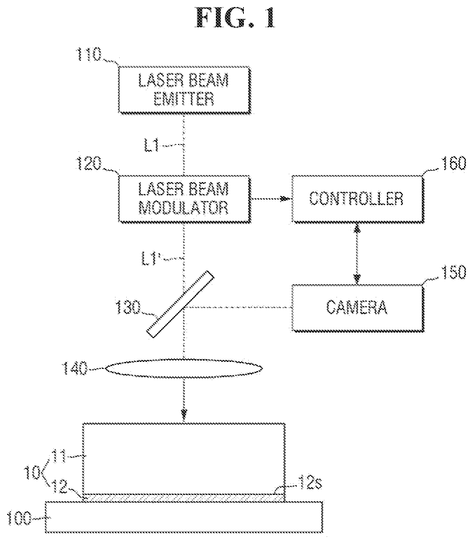

FIG. 1 is a view illustrating an apparatus for substrate dicing according to embodiments of the present inventive concept.

Referring to FIG. 1, an apparatus for substrate dicing according to some embodiments of the present inventive concept includes a stage 100, a laser beam emitter 110, a laser beam modulator 120, a transfer optical unit 130, an optical system 140, a camera 150 and a controller 160.

The apparatus for substrate dicing according to embodiments of the present inventive concept may be a stealth dicing laser apparatus. The stealth dicing laser apparatus may collect a laser beam for cutting a wavelength capable of transmitting a semiconductor substrate by an optical system to focus the laser beam on a point inside the semiconductor substrate. The focused laser beam for cutting may be configured with a short pulse that oscillates at a high repetition rate, and may be highly condensed to reach a threshold level of diffraction. The laser light for cutting in the semiconductor substrate may be collected at a very high peak power density near a light collecting point, and at the same time may be compressed spatially. When the laser light for cutting, which transmits to the semiconductor substrate, exceeds the peak power density in a condensing process, an extremely high non-linear multi-photon absorption phenomenon may occur near the light collecting point. Due to the high non-linear multi-photon absorption phenomenon occurring near the light collecting point, a crystal of the semiconductor substrate may absorb energy of the beam that is collected in the semiconductor substrate to cause a thermal melting phenomenon, thereby forming a reforming region and a crack. When the stealth dicing laser apparatus is used, only a local point in the substrate may be selectively processed without damaging a front surface and a rear surface inside the semiconductor substrate. In addition, the laser apparatus for cutting may include a mechanism for moving a relative position of the laser beam and the semiconductor substrate to cut the substrate at a high speed in accordance with a cutting pattern.

A test substrate 10 may be loaded onto the stage 100. The test substrate 10 includes a sample substrate 11 and a test film 12.

The test film 12 is disposed on the sample substrate 11. For example, the test film 12 may be disposed on a lower surface of the sample substrate 11. The test film 12 is in contact with the sample substrate 11. An upper surface 12s of the test film 12 may be in contact with the sample substrate 11.

The test film 12 may include a material capable of absorbing a wavelength of a laser beam L1. The test film 12 may include, for example, a metal. The test film 12 may include at least one, for example, tin, chromium, platinum and/or copper.

The laser beam emitter 110 provides the laser beam L1. The laser beam emitter 110 may adjust a power of the laser beam L1. The laser beam emitter 110 may adjust the power of the laser beam L1 under the control of the controller 160 or a separate controller other than the controller 160.

The laser beam modulator 120 may be disposed between the laser beam emitter 110 and the optical system 140. The laser beam modulator 120 may modulate the laser beam L1 to output a modulated beam L1′. The laser beam modulator 120 may modulate a shape and/or phase of the laser beam L1.

The laser beam modulator 120 may be, for example, a spatial light modulator (SLM).

The transfer optical unit 130 may be disposed between the optical system 140 and the camera 150. For example, the transfer optical unit 130 may be disposed between the laser beam modulator 120 and the optical system 140. The transfer optical unit 130 may transfer the modulated beam L1′ to the optical system 140. In addition, the transfer optical unit 130 may transfer the modulated beam L1′ that is reflected from the test substrate 10 to the camera 150. The transfer optical unit 130 may transfer the modulated beam L1′ that is reflected from the upper surface 12s of the test film 12 to the camera 150.

The transfer optical unit 130 may include various optical elements such as mirror and/or lens. The transfer optical unit 130 may include, for example, a dichroic mirror. For example, the transfer optical unit 130 may be disposed between the laser beam emitter 110 and the laser beam modulator 120.

The optical system 140 may be disposed between the laser beam modulator 120 and the stage 100. For example, the optical system 140 may be disposed between the transfer optical unit 130 and stage 100. The optical system 140 may transfer the modulated beam L1′ to the test substrate 10. For example, the optical system 140 may refract the modulated beam L1′ into the test substrate 10. As another example, the optical system 140 may focus the modulated beam L1′ into the test substrate 10.

The optical system 140 may include, for example, an objective lens.

The camera 150 may capture the modulated beam L′ that is reflected from the test substrate 10. For example, the camera 150 may capture an image of the test substrate 10. The camera 150 may capture the modulated beam L′ that is reflected from the upper surface 12s of the test film 12. For example, the camera 150 may capture an image of the test film 12. The camera 150 may form image data by detecting the modulated beam L1′ that is reflected from the upper surface 12s of the test film 12.

The controller 160 may receive the image data from the camera 150. The controller 160 may generate a control signal based on the image data. The laser beam modulator 120 may be corrected based on the control signal. The corrected laser beam modulator 120 may modulate the laser beam L1 based on the control signal to output the modulated beam L1′.

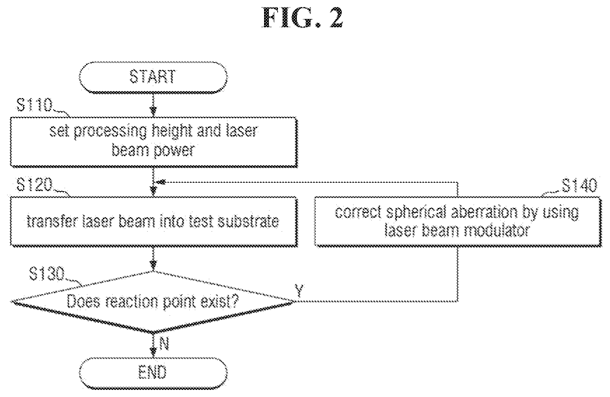

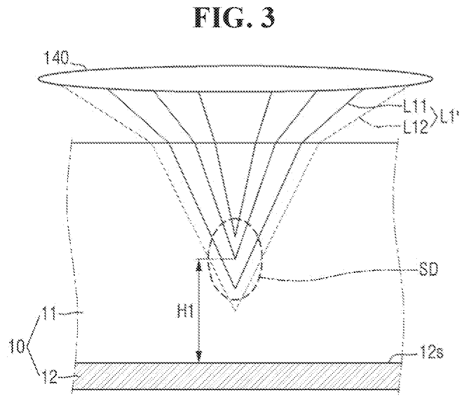

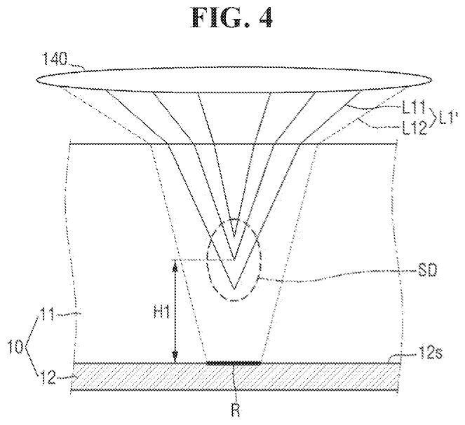

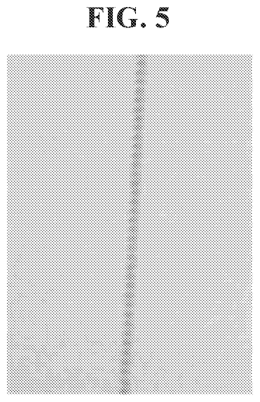

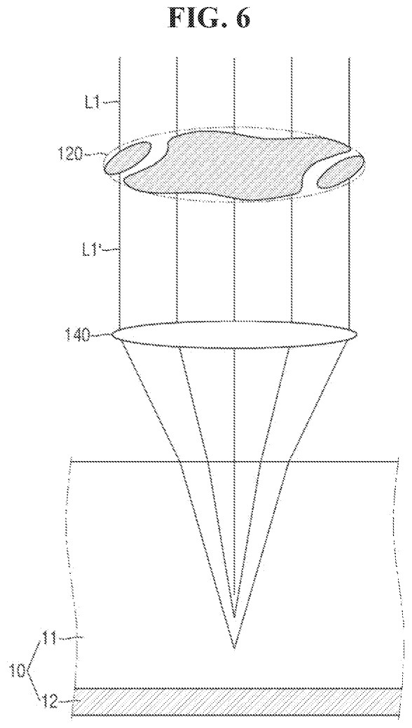

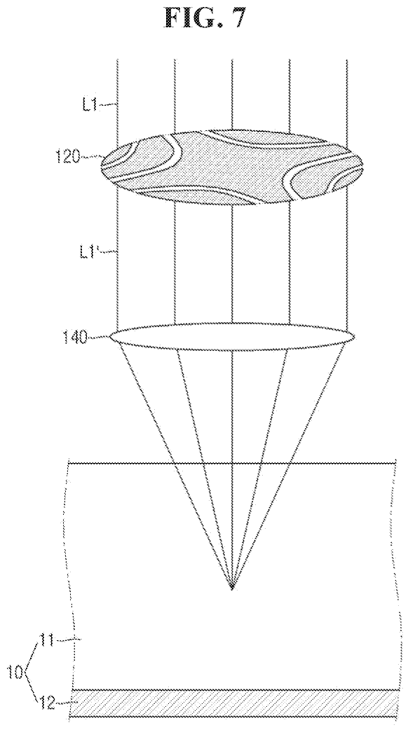

FIG. 2 is a flow chart illustrating an operation of an apparatus for substrate dicing according to embodiments of the present inventive concept. FIG. 3 is a view illustrating that spherical aberration of an apparatus for substrate dicing is normal. FIG. 4 is a view illustrating that spherical aberration of an apparatus for substrate dicing is defective. FIG. 5 is an example of image data obtained by capturing a test film on which a reaction point is formed. FIGS. 6 and 7 are views illustrating that aberration of an apparatus for substrate dicing is corrected using a laser beam modulator.

Referring to FIGS. 1 to 4, a processing height H1 and the power of the laser beam L1 are set to predetermined values (S110).

For example, the processing height H1 and the power of the laser beam L1 may be set by the controller 160 or a separate controller other than the controller 160.

The processing height H1 may refer to a height from the upper surface 12s of the test film 12 to the light collecting point where the optical system 140 transfers the modulated beam L1′ into the sample substrate 11.

The light collecting point when testing the apparatus for substrate dicing of FIG. 2 may be the same as a light collecting point when dicing a target substrate after testing the apparatus for substrate dicing. For example, the apparatus for substrate dicing may be tested under the same condition as the condition of dicing the target substrate except for the power of the laser beam L1.

The laser beam L1 has a power in which a reforming region is not formed in the test substrate 10. Even though the laser beam L1 is collected in the light collecting point in the sample substrate 11, that is, the processing height H1 in the sample substrate 11, the reforming region is not formed in the sample substrate 11. The laser beam modulator 120 may modulate the laser beam L1 to output the modulated beam L1′.

The modulated beam L1′ is transferred into the test substrate 10 (S120). The optical system 140 may transfer the modulated beam L1′ into the test substrate 10.

It is determined whether a reaction point exists in the test film 12 (S130).

Referring to FIG. 3, when the spherical aberration of the apparatus for substrate dicing is normal, the modulated beam L1′ does not reach the test film 12.

Referring to FIG. 4, when the spherical aberration of the apparatus for substrate dicing is defective, the modulated beam L1′ reaches the test film 12. The spherical aberration may occur due to performance degradation of optical components (e.g., the transfer optical unit 130, the optical system 140, etc.) in the apparatus for substrate dicing. A first beam L11 of the modulated beam L1′, which is incident on the center of the optical system 140, and a second beam L12 of the modulated beam L1′, which is incident on an outer portion of the optical system 140, each generate an angle that is different from their incident angles when passing through a boundary surface of the test substrate 10. For example, the angle of refraction of the first beam L11 may be different from the angle of incidence of the first beam L11, and the angle of refraction of the second beam L12 may be different from the angle of incidence of the second beam L12. In addition, as an example, the angle of incidence of the first beam L11 may be different from the angle of incidence of the second beam L12. Due to the difference between the incident angles, a deviation of a focal length of the optical system 140 may occur and spherical aberration may occur.

The test film 12 may include a material that absorbs the wavelength of the laser beam L1. Therefore, the second beam L12 may be absorbed by the test film 12, and may be vaporized by thermal energy to form a reaction point on the test film 12. The reaction point may be formed in a region R of the upper surface 12s of the test film 12 by the second beam L12.

When the laser beam L1 has a power in which a reforming region is formed in the sample substrate 11, it is difficult to distinguish the reaction point formed in the test film 12 from the reforming region due to interference with the reforming region formed in the sample substrate 11 by the laser beam L1.

However, in the method for testing an apparatus for substrate dicing according to embodiments of the present inventive concept, since the laser beam L1 has a power in which a reforming region is not formed in the sample substrate 11, it is easy to observe the reaction point formed in the test film 12.

For example, referring to FIG. 5, the reaction point may be formed on the upper surface 12s of the test film 12. The controller 160 may receive the image data, which is obtained by capturing the modulated light L′ that is reflected from the upper surface 12s of the test film 12, from the camera 150. The controller 160 may determine whether the reaction point exists on the upper surface 12s of the test film 12, based on the image data.

The controller 160 may determine whether the reaction point is formed in the test film 12, based on, for example, a gray component of the image data. For example, when different gray components exist in the image data, the controller 160 may determine that the reaction point is formed in the test film 12. For example, when different gray components do not exist in the image data (when only one gray component exists in the image data), the controller 160 may determine that the reaction point is not formed in the test film 12.

When the reaction point does not exist on the upper surface 12s of the test film 12 (S130), the test of the apparatus for substrate dicing is terminated.

When the reaction point exists on the upper surface 12s of the test film 12 (S130), aberration of a substrate test apparatus may be corrected by using the laser beam modulator 120 (S140).

For example, the controller 160 may generate a control signal indicating a gray component of the image data. The laser beam modulator 120 may correct a spherical aberration in accordance with the control signal.

Referring to FIGS. 6 and 7, the laser beam modulator 120 may store a plurality of correction patterns. The laser beam modulator 120 may select any one of the plurality of correction patterns in accordance with the control signal. The laser beam modulator 120 may generate the modulated beam L1′ by modulating the laser beam L1 by using the selected correction pattern.

As another example, the controller 160 may generate a control signal indicating any one of the plurality of correction patterns of the laser beam modulator 120 based on the gray component of the image data. The laser beam modulator 120 may generate the modulated beam L1′ by modulating the laser beam L1 by using the correction pattern that is selected in accordance with the control signal.

After spherical aberration of the apparatus for substrate dicing is corrected by using the laser beam modulator 120, the step S120 may be performed. The spherical aberration of the apparatus for substrate dicing may be corrected by using the laser beam modulator 120 until the reaction point does not exist in the test film 12.

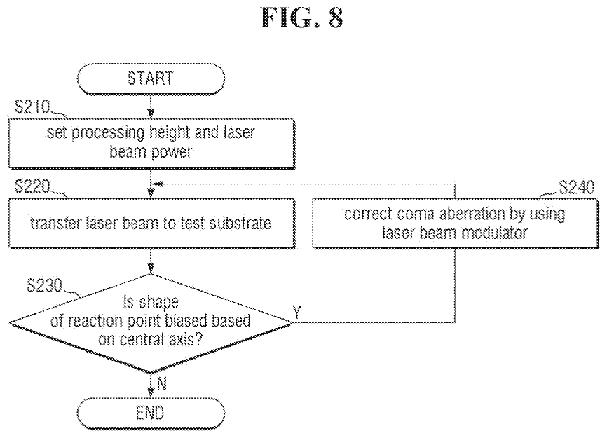

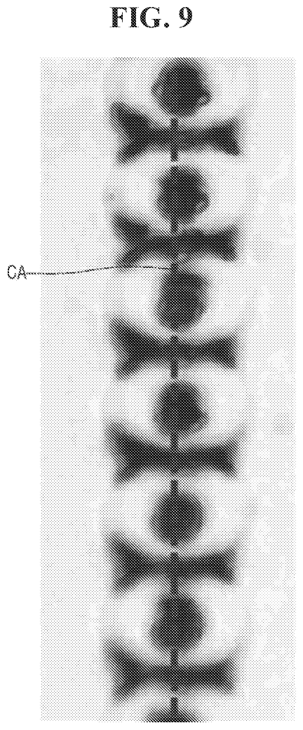

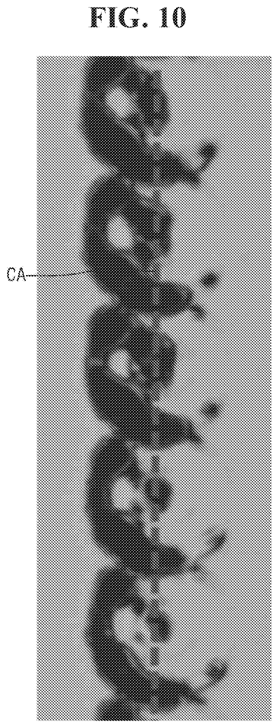

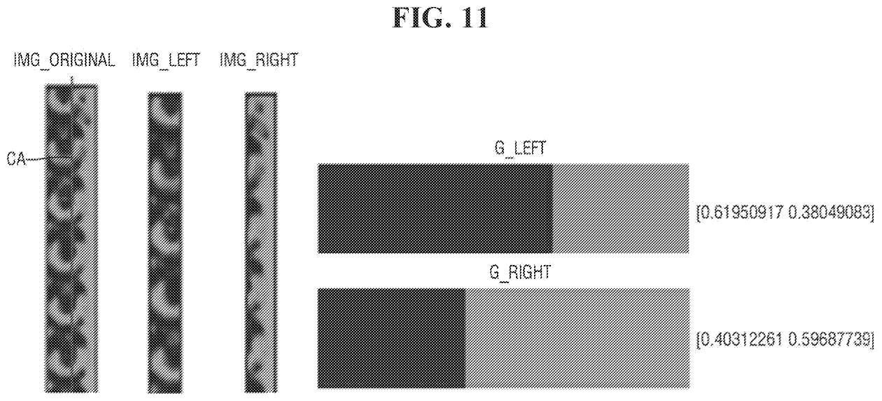

FIG. 8 is a flow chart illustrating an operation of an apparatus for substrate dicing according to embodiments of the present inventive concept. FIG. 9 is an example of image data when coma aberration of an apparatus for substrate dicing is normal. FIG. 10 is an example of image data when coma-aberration of an apparatus for substrate dicing is defective. FIG. 11 is a view illustrating a step S230 of FIG. 8.

For convenience of description, the following description will be based on differences from those described with reference to FIGS. 1 to 7, and redundant descriptions may be omitted or briefly discussed.

Referring to FIG. 1 and FIG. 8, the processing height H1 and the power of the laser beam L1 are set to predetermined values (S210).

The processing height set in step S210 of FIG. 8 may be different from the processing height set in the step S110 of FIG. 3. For example, the processing height set in the step S210 of FIG. 8 may be greater or smaller than the processing height set in the step S110 of FIG. 2. The light collecting point when testing the apparatus for substrate dicing according to FIG. 8 may be different from the light collecting point when dicing the target substrate after testing the apparatus for substrate dicing. The processing height H1 may be selected to observe the shape of the reaction point.

The laser beam L1 has a power in which the reforming region is not formed in the test substrate 10. For example, the power of the laser beam L1 set in the step S210 of FIG. 8 may be the same as the power of the laser beam L1 set in the step S110 of FIG. 3.

The modulated beam L1′ is transferred into the test substrate 10 (S220).

It is determined whether the shape of the reaction point formed in the test film 12 is biased based on a central axis (S230). For example, the controller 160 may receive the image data, that is obtained by capturing the modulated light L′ that is reflected from the upper surface 12s of the test film 12, from the camera 150. The controller 160 may determine, based on the image data, whether the shape of the reaction point that is formed on the upper surface 12s of the test film 12 is biased toward any one side of the upper surface 12s of the test film 12 with respect to the central axis on the upper surface 12s of the test film 12.

The central axis may be, for example, an axis extended in a vertical direction based on the center of the shape of the reaction point. Hereinafter, the central axis will be described as being in the vertical direction by way of example, but the present inventive concept is not limited thereto. The central axis may be a central axis in various directions, for example in a horizontal direction.

It may be determined whether the shape of the reaction point is biased based on a plurality of central axes. For example, it may be determined whether the shape of the reaction point is biased based on the central axis in the horizontal direction, and it may be determined whether the shape of the reaction point is biased based on the central axis in the vertical direction.

Referring to FIG. 9, when coma aberration of the apparatus for substrate dicing is normal, the shape of the reaction point is symmetric based on the central axis CA.

Referring to FIG. 10, when the coma aberration of the apparatus for substrate dicing is defective, the shape of the reaction point based on the central axis CA is biased toward one side based on the central axis CA on the upper surface 12s of the test film 12. The coma aberration may occur when an optical axis of the apparatus for substrate dicing is tilted by an external environment or the like. When the optical axis of the apparatus for substrate dicing is tilted, distribution of the modulated beam (L12 in FIG. 4) reaching the test film 12 may be varied. Therefore, the shape of the reaction point may be eccentric.

The controller 160 may determine whether the shape of the reaction point is biased with respect to the central axis CA based on, for example, the gray component of the image data.

Referring to FIG. 11, the controller 160 may divide image data IMG_ORIGINAL into first image data IMG_LEFT and second image data IMG_RIGHT with respect to the central axis CA. The first image data IMG_LEFT is image data disposed on one side with respect to the central axis CA, and the second image data IMG_RIGHT is image data disposed on the other side with respect to the central axis CA. The controller 160 may generate a control signal by calculating a gray component of the first image data IMG_LEFT and a gray component of the second image data IMG_RIGHT.

The controller 160 may calculate a first gray level value and a second gray level value G_LEFT of the first image data IMG_LEFT. The first gray level value and the second gray level value G_LEFT may be calculated by a ratio that is occupied by the first gray level and the second gray level in the first image data IMG_LEFT, respectively. The controller 160 may calculate a first gray level value and a second gray level value G_RIGHT of the second image data IMG_RIGHT. The first gray level value and the second gray level value G_RIGHT may be calculated by a ratio that is occupied by the first gray level and the second gray level in the second image data IMG_RIGHT, respectively.

The controller 160 may determine that the shape of the reaction point is biased with respect to the central axis CA when the first gray level value and the second gray level value G_LEFT of the first image data IMG_LEFT are different from the first gray level value and the second gray level value G_RIGHT of the second image data IMG_RIGHT. Since the first gray level value and the second gray level value G_LEFT of the first image data IMG_LEFT are [0.61950917, 0.38049083] and the first gray level value and the second gray level value G_RIGHT of the second image data IMG_RIGHT are [0.40312261, 0.59687739], which are different from each other, the controller 160 may determine that the shape of the reaction point is biased with respect to the central axis CA.

When the shape of the reaction point is not biased based on the central axis CA (S230), the test of the apparatus for substrate dicing is terminated.

When the shape of the reaction point is biased to one side based on the central axis CA (S230), aberration of the substrate test apparatus may be corrected by using the laser beam modulator 120 (S240).

For example, the controller 160 may generate a control signal indicating the first gray level value and the second gray level value of the first image data IMG_LEFT and the first gray level value and the second gray level value of the second image data IMG_RIGHT. The laser beam modulator 120 may correct a coma aberration in accordance with the control signal.

The laser beam modulator 120 may correct aberration of the substrate test apparatus as described with reference to FIGS. 6 and 7.

After the coma aberration of the apparatus for substrate dicing is corrected by using the laser beam modulator 120, the step S220 may be performed. The coma aberration of the apparatus for substrate dicing may be corrected by using the laser beam modulator 120 until the shape of the reaction point is not biased with respect to the central axis CA, that is, until the shape of the reaction point is not eccentric.

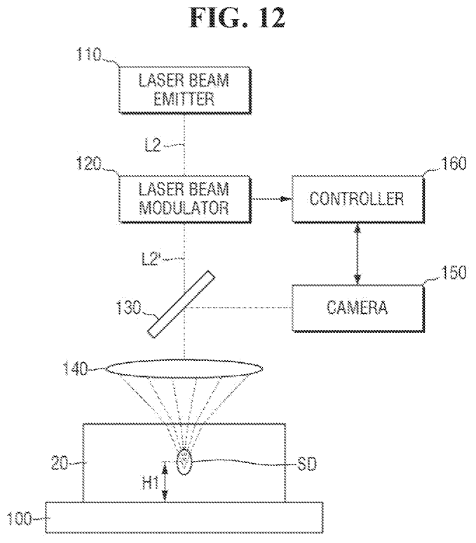

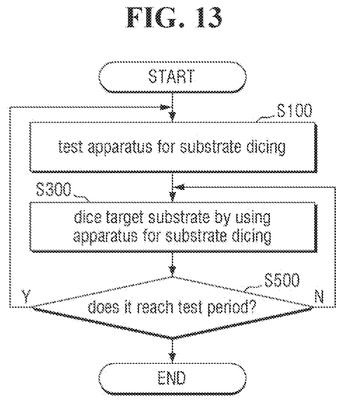

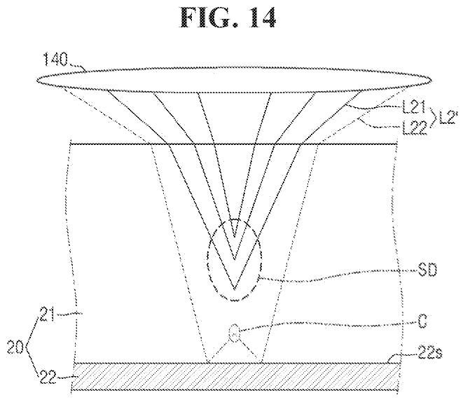

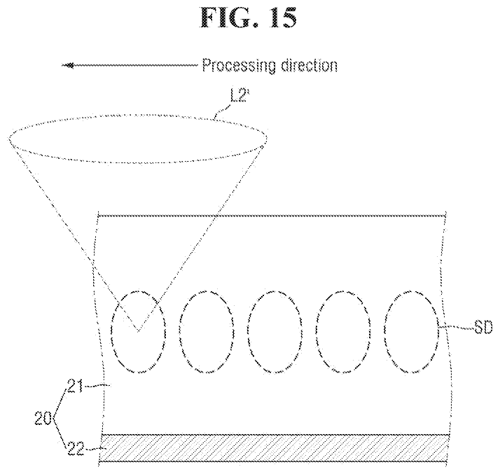

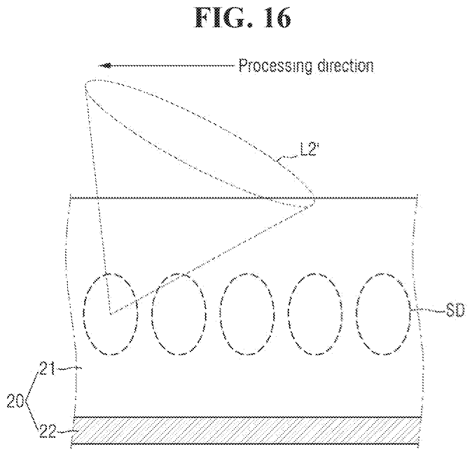

FIG. 12 is a view illustrating an operation method of an apparatus for substrate dicing according to embodiments of the present inventive concept. FIG. 13 is a flow chart illustrating an operation method of an apparatus for substrate dicing according to embodiments of the present inventive concept. FIG. 14 is a view illustrating that a spherical aberration of an apparatus for substrate dicing is defective. FIG. 15 is a view illustrating that coma-aberration of an apparatus for substrate dicing is normal. FIG. 16 is a view illustrating that coma-aberration of an apparatus for substrate dicing is defective.

Referring to FIGS. 12 and 13, the apparatus for substrate dicing is tested (S100).

Testing of the apparatus for substrate dicing may include at least one of a test method of the apparatus for substrate dicing, which will be described with reference to FIG. 1 to 7, or a test method of the apparatus for substrate dicing, which will be described with reference to FIGS. 8 to 11.

A target substrate 20 is diced by using the apparatus for substrate dicing (S300).

The test substrate (10 of FIG. 1) may be unloaded from the stage 100, and the target substrate 20 may be loaded onto the stage 100.

The laser beam emitter 110 provides the laser beam L2. The power of the laser beam L2 for dicing the target substrate 20 may be different from the power of the laser beam (L1 of FIG. 1) for testing the apparatus for substrate dicing by using the test substrate 10. The power of the laser beam L2 for dicing the target substrate 20 may be greater than the power of the laser beam L1 for testing the apparatus for substrate dicing by using the test substrate 10.

The laser beam modulator 120 modulates the laser beam L2 to output the modulated beam L2′. The laser beam modulator 120 may be corrected through the step S100. The modulated beam L2′ may be generated through the laser beam modulator 120 that is corrected through the step S110.

The optical system 140 collects the modulated beam L2′ into the target substrate 20. The optical system 140 collects the modulated beam L2′ into the light collecting point that is inside the target substrate 20. The position of the light collecting point in the target substrate 20 is the same as the position of the light collecting point in the test substrate 10.

The modulated beam L2′ may concentrate energy near the light collecting point. The modulated beam L2′ collected near the light collecting point that is inside the target substrate 20 may form a reforming region SD and a crack. The crack may be formed in the reforming region SD. The laser beam emitter 110, the laser beam modulator 120 and the optical system 140 may form a reforming region SD and a crack in the target substrate 20 and then may move in a processing direction to form a plurality of reforming regions SD and cracks in the target substrate 20. As the plurality of reforming areas and the cracks are formed, the target substrate 20 may be unbalanced in force between molecules, and when an external force is applied to the target substrate 20, the target substrate 20 may be naturally divided based on the reforming region SD and the crack.

Referring to FIG. 14, the target substrate 20 may include a substrate 21 and a metal layer 22. The substrate 21 may include, for example, silicon. The metal layer 22 may be disposed on the substrate 21. For example, the metal layer 22 may be disposed on a lower surface of the substrate 21. The metal layer 22 may be a layer in which a semiconductor device is formed. A thickness of the sample substrate 11 may be the same as that of the substrate 21.

The sample substrate (11 of FIG. 1) may include the same material as that of the substrate 21. The thickness of the sample substrate 11 may be the same as that of the substrate 21. In this case, the thickness may be defined based on a direction perpendicular to an upper surface of the stage 100 on which the test substrate 10 is loaded. A height from a lower surface of the substrate 21 to the light collecting point may be the same as the processing height H1 set in the step S110 of FIG. 2.

When the target substrate 20 is diced by using the apparatus for substrate dicing in which spherical aberration is defective, the reforming region SD may be formed in the substrate 21 by a first beam L21 of the modulated beams L2′, and a second beam L22 of the modulated beam L21′, which has an increased focal length due to spherical aberration, may be reflected from an upper surface 22s of the metal layer 22 and then re-collected in the substrate 21. A crack C may be formed in the substrate 21 by the re-collected second beam L22, and thus, strength of the target substrate 20 may be deteriorated.

However, in the apparatus for substrate dicing according to embodiments of the present inventive concept, since the target substrate 20 is diced after spherical aberration is corrected, strength of the target substrate 20 may be increased.

Referring to FIGS. 15 and 16, when the target substrate 20 is diced by using the apparatus for substrate dicing, in which coma aberration is defective, a spatial overlap may be increased between the modulated beam L2′ and the reforming region SD that is already formed, as compared with the case that the target substrate 20 is diced by using the apparatus for substrate dicing, in which coma aberration is defective. Therefore, a portion of the modulated beam L2′ may be reflected from the reforming region SD and scattered in the target substrate 20, and the scattered modulated beam L2′ may cause optical damage to the semiconductor devices that are formed in the target substrate 20.

However, in the apparatus for substrate dicing according to embodiments of the present inventive concept, since the target substrate 20 is diced after coma aberration is corrected, the semiconductor devices may be prevented from being damaged.

In addition, it is difficult to detect aberration after the optical system 140, from the laser beam emitter 110, due to a space on the facility. However, the apparatus for substrate dicing according to embodiments of the present inventive concept may detect aberration after the optical system 140 by using at least one of the test method of the apparatus for substrate dicing, which is described with reference to FIGS. 1 to 7, and the test method of the apparatus for substrate dicing, which is described with reference to FIGS. 8 to 11, and thus, may correct the laser beam modulator 120.

The target substrate may be diced (S300) until a test period is reached (S500). When the test period is reached (S500), the apparatus for substrate dicing may be tested again (S100). For example, the test (S100) of the apparatus for substrate dicing may be periodically performed. For example, the test period may be set based on whether the apparatus for substrate dicing has diced N (N is a natural number) target substrates.

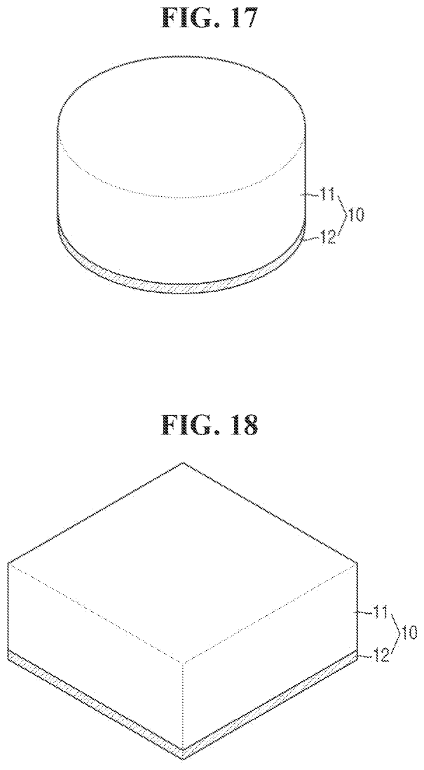

FIGS. 17 and 18 are view illustrating the test substrate of FIG. 1.

Referring to FIG. 17, in embodiments of the present inventive concept, the test substrate 10 may have a wafer shape.

Referring to FIG. 18, in embodiments of the present inventive concept, the test substrate 10 may be a cut wafer. For example, the test substrate 10 may have a rectangular parallelepiped shape, but the present inventive concept is not limited thereto. The test substrate 10 may have various shapes. The test substrate 10 may have any shape that includes the sample substrate 11 and the test film 12.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. An apparatus for substrate dicing comprising:
a laser beam emitter configured to output a laser beam;
a stage on which a test substrate is loaded, wherein the test substrate includes a sample substrate and a test film that is disposed on the sample substrate;
a laser beam modulator configured to modulate the laser beam and to output a modulated beam;
an optical system configured to transfer the modulated beam into the sample substrate;
a camera configured to capture the modulated beam that is reflected from the test film; and
a controller configured to generate a control signal based on at least one of a reaction point being formed in the test film or a shape of the reaction point of the test film being biased toward one side with respect to a central axis,
wherein the laser beam modulator is configured to modulate the laser beam based on the control signal and to output the modulated beam that is based on the control signal,
the test film includes a material for absorbing the modulated beam, and
the laser beam has a power in which a reforming region is not formed in the test substrate.

2. The apparatus of claim 1, wherein the controller is configured to generate the control signal based on a degree of the shape of the reaction point formed in the test film, which is biased toward one side with respect to the central axis.

3. The apparatus of claim 1, wherein the camera is configured to generate an image data by capturing the modulated beam that is reflected from the test film, and
the controller determines whether the reaction point is formed in the test film and whether the shape of the reaction point is biased toward one side with respect to the central axis, based on a gray component of the image data.

4. The apparatus of claim 1, wherein the controller is configured to generate the control signal based on whether the reaction point is formed in the test film when the optical system is configured to receive the modulated beam from an upper surface of the test film to a first processing height, and
wherein the controller is configured to generate the control signal based on the shape of the reaction point when the optical system is configured to receive the modulated beam from the upper surface of the test film to a second processing height.

5. The apparatus of claim 4, wherein the first processing height is different from the second processing height.

6. The apparatus of claim 1, wherein the test film includes a metal.

7. The apparatus of claim 6, wherein the test film includes at least one of tin, chromium, platinum or copper.

8. The apparatus of claim 1, wherein the central axis is a central axis in a vertical direction.

9. An apparatus for substrate dicing comprising:
a laser beam emitter configured to output a laser beam;
a stage on which a test substrate is loaded, wherein the test substrate includes a sample substrate and a test film that is disposed on the sample substrate;
a laser beam modulator configured to modulate the laser beam and to output a modulated beam;
an optical system configured to transfer the modulated beam into the sample substrate;
a camera configured to capture the modulated beam that is reflected from the test film to generate an image data; and
a controller configured to generate a control signal based on the image data,
wherein the laser beam modulator is configured to modulate the laser beam based on the control signal and to output the modulated beam that is based on the control signal,
the test film includes a material for absorbing the laser beam, and
the laser beam has a power in which a reforming region is not formed in the test substrate.

10. The apparatus of claim 9, wherein the controller is configured to generate the control signal based on a gray component of the image data.

11. The apparatus of claim 9, wherein the controller is configured to generate the control signal based on a presence of different gray components of the image data.

12. The apparatus of claim 9, wherein the controller is configured to generate the control signal by calculating a gray component on one side of the image data based on a central axis in a set direction and calculating a gray component on another side of the image data based on the central axis.

13. The apparatus of claim 9, wherein the test film includes a metal.

14. An apparatus for substrate dicing comprising:
a laser beam emitter configured to output a first laser beam;
a stage on which a test substrate is loaded, wherein the test substrate includes a sample substrate and a test film that is disposed on the sample substrate;
a laser beam modulator configured to modulate the first laser beam;
an optical system configured to transfer the modulated first laser beam into the test substrate;
a camera configured to capture the modulated first laser beam that is reflected from the test film to generate image data; and
a controller configured to generate a control signal based on a gray component of the image data,
wherein the laser beam modulator is configured to be corrected based on the control signal,
when the test substrate is unloaded from the stage and a target substrate is loaded on the stage, the laser beam emitter is configured to output a second laser beam, the corrected laser beam modulator is configured to modulate the second laser beam, and the optical system is configured to transfer the modulated second laser beam into the target substrate, and
the first laser beam has a power in which a reforming region is not formed in the sample substrate.

15. The apparatus of claim 14, wherein the controller is configured to generate the control signal based on a presence of different gray components of the image data when the optical system is configured to transfer the modulated first beam from an upper surface of the test film to a first processing height, and
the controller is configured to generate the control signal by calculating a gray component on one side of the image data based on a central axis and calculating a gray component on the another side of the image data based on the central axis when the optical system is configured to receive the modulated first laser beam from the upper surface of the test film to a second processing height.

16. The apparatus of claim 15, wherein the first processing height is different from the second processing height.

17. The apparatus of claim 16, wherein the optical system is configured to receive the modulated second laser beam from a lower surface of the target substrate to the first processing height.

18. The apparatus of claim 14, wherein a power of the second laser beam is greater than that of the first laser beam.

19. The apparatus of claim 14, wherein the test film includes a metal.

20. The apparatus of claim 19, wherein the test film includes at least one of tin, chromium, platinum or copper.
